(19) United States
(12) Patent Application Publication
(10) Pub. No.: US 2024/0427249 A1
(43) Pub. Date: Dec. 26, 2024

(54) Self-Adhesive Graphite Film Positive

(71) Applicant: Patrick Gerald McCkintock, Port Hueneme, CA (US)

(72) Inventor: Patrick Gerald McCkintock, Port Hueneme, CA (US)

(21) Appl. No.: 18/214,423

(22) Filed: Jun. 26, 2023

(51) Int. Cl. G03F 7/12

(52) U.S. Cl. CPC G03F 7/12; G02B 5/22

(57) ABSTRACT

Graphite images may be translated into printable forms by use of a Self-Adhesive Graphite Film Positive. Graphite is used to block the passage of light wave energy. In the case of silk screen print making a self-adhesive backing member is used in conjunction with the Graphite Positive to prevent the backscatter of light.

### FIELD

This invention relates to the creation of a film positive.

### BACKGROUND

Film positives are used in the printing industry. For example, a film positive may be placed over a photo sensitized silk screen or other media that is then placed into a vacuum frame. The air vacuumed out brings the ink image of the film into intimate contact with the photo sensitized screen. This is done prior to exposure to UV light. The image of the film positive is by exposure to a light source transposed to the photo sensitized screen. The image of the film positive is then ready to print.

The method used to employ a Self-Adhesive Graphite Film Positive will accomplish the same thing as a will a conventional positive used with a vacuum frame. But because the Graphite Positive is self-adhesive a vacuum frame will not be needed. This reduces costs, a valuable means to the home-based print maker. The combination of a Graphite Positive placed onto a photosensitized silk screen and an opaque, self-adhesive film or member placed onto the opposing side to the Graphite positive of the screen, eliminates the vacuum frame requirement.

Transfer films are not used to transpose pencil drawings into printable forms.

A Graphite Positive takes advantage of the properties of graphite. That is it has properties related to light absorption and light reflectance.

Graphite in scientific terms absorbs the ordinary ray while reflecting the extraordinary ray of light.

This allows it to replace black ink as an effective way to block the passage of light wave energy. Graphite will also block the passage of light over the entire light wave spectrum.

It is more cost effective to use a Graphite Film Positive to translate a graphite pencil drawn image into a printable form. Albeit there are more artists that begin with pencil drawing than any other media. Graphite Film Positives make for a unique printing method derived directly from a graphite drawing. It is effective, easy, and affordable. A Self-Adhesive Graphite Film Positive constitutes a unique method for the making of printed matter derived from pencil drawings and it is an unknown technique today.

Existing techniques in the Arts and Crafts Industry do not utilize graphite to block the passage of light wave energy during exposure of screens or etching and lithographic plates. The Graphite Positive method takes advantage of the unique properties of graphite to block the passage of light wave energy. The Graphite Positive method constitutes a new mythology to cottage industry print making and to professional fine arts printing as well.

### SUMMARY

A Self-Adhesive Graphite Film Positive eliminates the need for a vacuum frame, a prohibitively costly piece of equipment to home-based industry or to hobbyists. It also eliminates the need for Computer and or Camera generated color separation films. Color separations may be made by hand in this method.

Graphite absorbs the ordinary ray of light wave energy and reflects the extraordinary ray. In addition, graphite will do so across the entire light wave spectrum. Therefor by both absorption and reflection graphite can serve as an effective means to the blocking of Light wave energy.

It is noted that the image carried by a Graphite Positive will be brought into intimate contact with the photo emulsion of the printmaking means because the embedded image of the film is on the same side of the film as is repositionable adessive of the Graphite Positive. When drawing in pencil on stipple or coquille board drawings are automatically half-toned. These kinds of drawings make half-tone printed images possible as well, thus eliminating the need for normal half-tone positives.

The average hobbyist can now enjoy the full benefit of expressing his or her creativity in the realm of printmaking. Printed multiples of any creative ilk are possible from greeting cards to children's art printmaking in any color can be derived from pencil drawings in any complexity to the most simple of creative forms.

Hand generated Half-tone images also constitute an entirely new and cost-effective way to generate printed matter derived from graphite drawings. This will be a boon to the home-based cottage industry of Arts and Crafts and to fine arts printmaking in general.

Because graphite will block the passage of not only UV light but of all light across the light wave spectrum new uses of graphite to inhibit light wave energy have yet to be realized.

### BRIEF DESCRIPTIONS OF DRAWINGS

FIG. 1 is a new sheet.

FIG. 2-2 is represented on replacement sheet FIG. 4 as Fig. 4-2, in replacement sheet FIG. 5 as FIG. 5-4, and in replacement sheet FIG. 6 as FIG. 6-7.

FIG. 3, formerly Sheet, sees element FIG. 3-2 in replacement sheet FIG. 4-2, in replacement sheet FIG. 5-4 and in replacement sheet FIG. 6-7.

FIG. 3-3 is reflected in replacement sheet FIG. 5-5, and replacement sheet FIG. 6-8

### BRIEF DESCRIPTION OF DRAWINGS

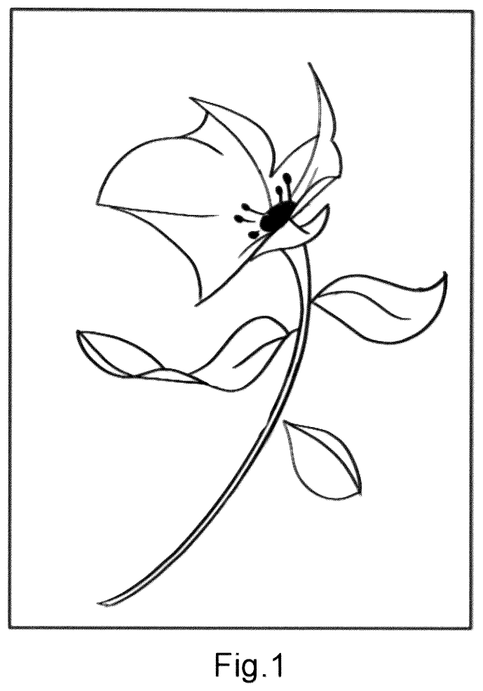

FIG. 1 shows a graphite pencil drawing made onto paper.

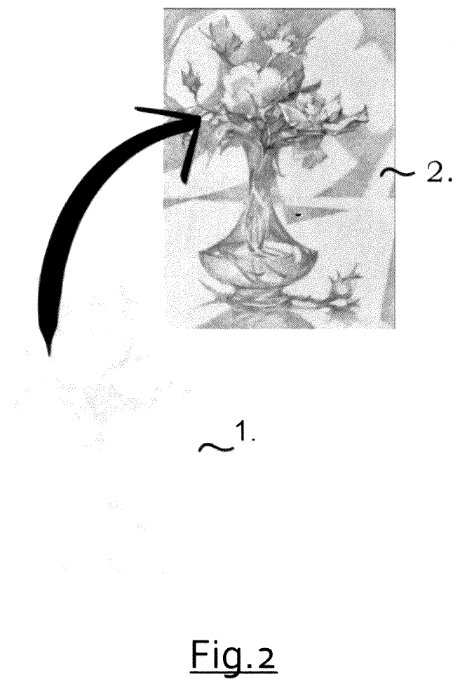

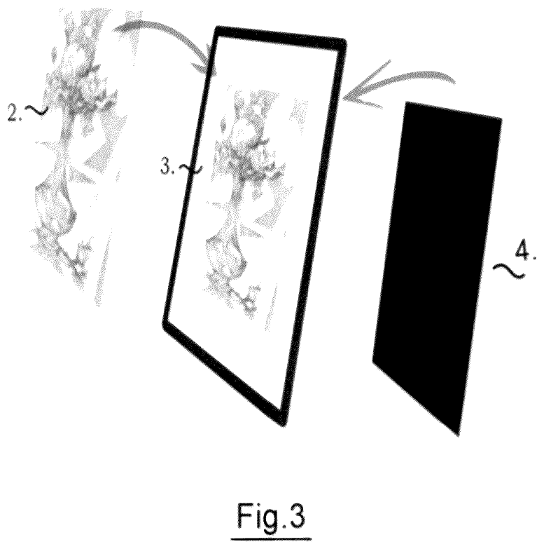

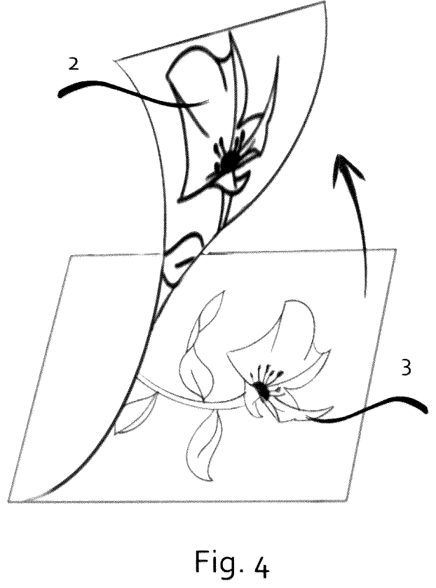

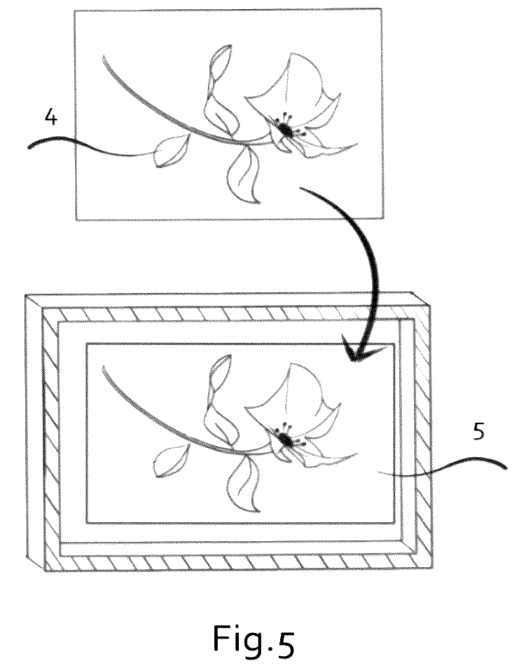

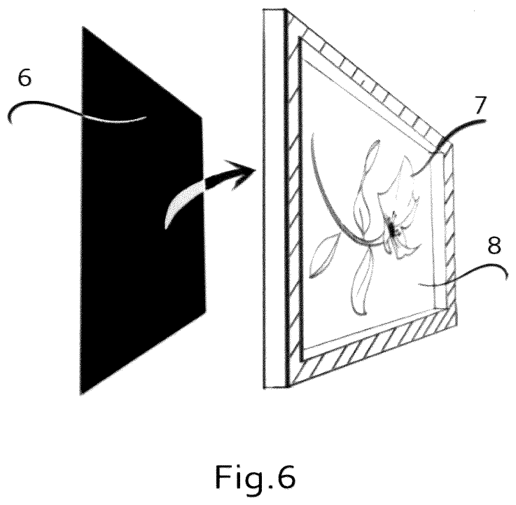

FIG. 4 shows a graphite positive FIG. 4-2. Left behind in FIG. 4-3 is a ghost image of the original graphite of the graphite drawing of FIG. 1.

FIG. 5 shows the Graphite Positive, FIG. 5-4 being adhered to a photosensitized silk screen, FIG. 5-5.

FIG. 6 shows a self-adhesive opaque to light backing member adhered opposite to the Graphite Positive, FIG. 6-7 on a sensitized silk screen, FIG. 6-8.

### DETAILED DESCRIPTION; SPECIFICATION

Reference application Ser. No. 16/350/775 filed on Jan. 9, 2019.

Graphite as found in ordinary pencils FIG. 1-1 becomes a means to block the passage of light wave energy. An improved film will pick up graphite from a drawing surface and is used as a Self-Adhesive Graphite Film Positive.

The Graphite Positive has been optimized to work as a Graphite Positive. It is 4ml to 6 ml thick and stiffer than normal transfer film. This prevents the film from easily folding over on itself and thus ruining a day's work. It has a low-tack adhesive surface so as not to tear the papers a drawing is lifted from by the optimized transfer film. The transfer takes place by burnishing the film over the drawing FIG. 4-2. The optimized Self-Adhesive Film Positive will be referred to here after as a Graphite Positive.

The Graphite Positive FIG. 5-4 is placed onto a photo sensitized silk screen FIG. 5-5. It is smoothed over by hand. It is noted that the graphite image occupies the side of the Graphite Positive as does the repositionable adhesive of the Graphite Positive. It is the means by which a graphite image blocks light wave energy and translates the graphite image into a printable form.

The Graphite Positive FIG. 5-4 is brought into intimate contact with the print making means by reason of its self-adhesive property FIG. 5-5. A backing film FIG. 6-6 of either black or a UV absorbing color that is also a self-adhesive member is placed onto the opposite side to the Graphite Positive FIG. 6-7 on the sensitized silk screen FIG. 6-8. This sandwich-like combination eliminates the need for a vacuum frame. The opaque sheet because it too is in intimate contact with the screen and prevents the back scatter of light during screen exposure to UV light. The Graphite Positive FIG. 6-4 combined with the Backing Member FIG. 6-6 translates the image successfully into a printable form.

The graphite image FIG. 1-1 embedded in the Graphite Positive FIG. 4-2 takes advantage of the unique property of graphite. It absorbs the ordinary ray of light energy and reflects the extraordinary ray. This property makes graphite a good choice to the making of a Graphite Positive. The graphite in the Graphite Positive adhesive surface serves to prevent light wave energy from reaching the photo sensitized print making means. Where the emulsion is exposed, the emulsion hardens, where the emulsion is protected from light by the Graphite Positive it remains soft. The screen is washed of its soft emulsion and the image is ready to print. It is noted that the property of graphite to absorb and reflect light extends to the entire light wave spectrum. It is further noted that the use of graphite to block light wave energy may have uses that are not yet realized.

This method of printmaking from a graphite source is a new methodology to the printmaking Arts and Crafts community. To home-based industry and to printmaking it will become a great asset due to the reduced cost of use. It is also unique to use graphite as a means to produce a printable form.

In the case of etching and lithographic photosensitized plates a Graphite Positive will work without the placement of a backing member.

In its first embodiment graphite is used to inhibit the passage of light wave energy across the entire light wave spectrum.

In its second embodiment graphite is used in the form of a Self-Adhesive Graphite Film Positive by its ability to block the passage of light energy by absorbing the ordinary ray and by reflecting the extraordinary ray.

In its third embodiment a Graphite Film Positive is used alone without a backing member as Lithographic plate exposure and etching plate exposure do not require a backing member.

1. A Self-Adhesive Graphite Film Positive.

2. The Self-Adhesive Graphite Film Positive of claim one and a self-adhesive opaque member where both are placed onto opposite sides of a photosensitized silk screen to make printable images derived from graphite.

3. Said Self-Adhesive Graphite Positive of claim one for inhibiting the passage of light wave energy.

4. Graphite means to translate images into printable forms.

5. The Graphite means of claim four to inhibit the passage of light wave energy.
